(19) United States
(12) Patent Application Publication
(10) Pub. No.: US 2023/0420548 A1
(43) Pub. Date: Dec. 28, 2023

(54) MAGNETIC STRUCTURES FOR RESONANT MANIPULATION OF SPIN

(71) Applicant: INTERNATIONAL BUSINESS MACHINES CORPORATION, ARMONK, NY (US)

(72) Inventors: Michele Aldeghi, Cadro (CH); Rolf Allenspach, Rueschlikon (CH); Gian R. von Salis, Aeugst am Albis (CH)

(21) Appl. No.: 17/808,972

(22) Filed: Jun. 24, 2022

(51) Int. Cl. H01L 29/66

(52) U.S. Cl. CPC H01L 29/66977

(57) ABSTRACT

A qubit system for quantum computing includes a semiconductor structure, an array of plunger gates, and an array of magnetic structures. The array of gates is above the semiconductor structure forming a linear one-dimensional (1D) array of quantum dots (QDs) in the semiconductor structure. The array of magnetic structures generates stray fields in the same plane as the array of QDs. The QDs in the array are positioned between poles of individual magnetic structures in the array of magnetic structures. An external field is applied in a direction that is parallel to the linear 1D array of QDs. The external field is adjusted to allow the magnetization of the magnetic structure to create a stray field that leads to different total magnetic fields at different qubit locations.

### BACKGROUND

### Technical Field

The present disclosure generally relates to quantum computing.

### Description of the Related Arts

Quantum computation exploits quantum phenomena for information processing and communication. Various models of quantum computation exist, and the most popular models include the concepts of qubits and quantum gates. A qubit is a generalization of a bit that has two possible states, but can be in a quantum superposition of both states. A quantum gate describes the transformation that one or more qubits will experience after the gate is applied on them, given their initial state. Various quantum phenomena, such as superposition and entanglement, do not have analogs in the world of classical computing and therefore may involve special structures, techniques, and materials.

Employing individual electron spins in semiconductor quantum dots as qubits is a promising route towards quantum information processing in solid-state systems. There are different methods of implementing single-qubit logic gates, and they are based on the manipulation of the electron's spin. The manipulation can be performed by electron spin resonance, which can be induced by an oscillating magnetic field, oscillating spin-orbit interaction, and inhomogeneous magnetic stray-field. Generally, a single-qubit gate may be implemented by a controlled rotation of an individual electron spin. The design of such an electron spin single-qubit gate has two main goals: (i) the manipulation of one electron spin should not affect neighboring qubits, and (ii) the manipulation of electron spin should be as fast as possible while minimizing the spin decoherence.

### SUMMARY

Some embodiments of the disclosure provide a qubit system that uses resonant manipulation of electron spin for qubits. The system includes a semiconductor structure, an array of gates, and an array of magnets or magnetic structures. The array of gates forms a linear one-dimensional (1D) array of quantum dots (QDs) in the semiconductor structure. The array of magnetic structures generates stray fields in the same plane as the array of QDs. The QDs are positioned between poles of individual magnetic structures in the array of magnetic structures. In some embodiments, the QDs in the array are positioned based on (i) the centers of individual magnets in the array of magnetic structures and (ii) the centers of gaps between individual magnetic structures.

In some embodiments, each magnetic structure has two separated arms that correspond to the two poles of a magnet. The center of each magnetic structure is at the middle position between the two arms. In some embodiments, each arm of the magnetic structure has a triangular notch or is rounded. The array of gates may include interleaving plunger gates that are aligned with the QDs and barrier gates that are aligned between the QDs and also with the poles of the magnetic structures.

In some embodiments, the array of magnetic structures is placed within 100 nm of the array of QDs. In some embodiments, an external field is applied in a direction that is parallel to the linear 1D array of QDs. The external field strength is adjusted to allow the magnetization of each magnetic structure to lie along the arms of the magnet but not aligned with the external field. At the different QD positions, different local magnetic fields exist and hence the QDs have different Larmor frequencies.

In some embodiments, each magnetic structure contains a ferro- or ferrimagnetic material which may include a combination of iron, cobalt, nickel, and gadolinium. In some embodiments, the plunger gates are constructed from magnetic materials.

By using the above-mentioned arrangement, the system achieves: (1) high driving gradient, which allows fast manipulation time, (2) low decoherence gradients, so that spin decoherence due to charge noise is small, and (3) differences in local magnetic fields among neighboring electrons, so that single qubit addressability is enhanced.

The preceding Summary is intended to serve as a brief introduction to some embodiments of the disclosure. It is not meant to be an introduction or overview of all inventive subject matter disclosed in this document. The Detailed Description that follows and the Drawings that are referred to in the Detailed Description will further describe the embodiments described in the Summary as well as other embodiments. Accordingly, to understand all the embodiments described by this document, a Summary, Detailed Description and the Drawings are provided. Moreover, the claimed subject matter is not to be limited by the illustrative details in the Summary, Detailed Description, and the Drawings, but rather is to be defined by the appended claims, because the claimed subject matter can be embodied in other specific forms without departing from the spirit of the subject matter.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all of the components or steps that are illustrated. When the same numeral appears in different drawings, it refers to the same or like components or steps.

FIG. 1 conceptually illustrates a design for electric dipole spin resonance (EDSR) driven electron-spin qubits, in which quantum dots are arranged in a 1D array, consistent with an illustrative embodiment.

FIG. 2 illustrates a qubit system with a nanomagnet design for magnetic stray-field, consistent with an illustrative embodiment.

FIG. 3 illustrates the stray-field outside the magnets and the demagnetizing field within the magnets resulting from the horseshoe magnetic structure, consistent with an illustrative embodiment.

FIG. 4 illustrates various designs for the ending part of the arm of a nanomagnet, consistent with an illustrative embodiment.

FIG. 5 shows plots of driving gradients at different types of QD positions, consistent with an illustrative embodiment.

FIGS. 6A-B conceptually illustrate example magnetic structures with alternative shapes that are used to support QDs.

FIGS. 7A-C conceptually illustrate example configuration of magnetic structures that forms 2D arrays of QDs for a EDSR qubit system.

### DETAILED DESCRIPTION

In the following detailed description, numerous specific details are set forth by way of examples in order to provide a thorough understanding of the relevant teachings. However, it should be apparent that the present teachings may be practiced without such details. In other instances, well-known methods, procedures, components, and/or circuitry have been described at a relatively high-level, without detail, in order to avoid unnecessarily obscuring aspects of the present teachings.

Employing individual electron spins in semiconductor quantum dots as qubits is a promising route towards quantum information processing in solid-state systems. There are different methods of manipulating the spin of a single electron, including electron spin resonance induced by an oscillating Oersted field, oscillating spin-orbit interaction, and inhomogeneous magnetic stray-field. Examples of these methods of manipulating electron spin can be found in e.g., Loss D., DiVincenzo D. P. (1998), “Quantum computation with quantum dots”, Phys. Rev. A, 57, 120-126; Pla, J., Tan, K., Dehollain, J. et al, “A single-atom electron spin qubit in silicon”, Nature 489, 541-545 (2012); K. C. Nowack, F. H. L. Koppens, Yu. V. Nazarov, L. M. K. Vandersypen, “Coherent Control of a Single Electron Spin with Electric Fields”, Science 30 Nov. 2007: 1430-1433; and R. Allenspach, G. Salis, U.S. Pat. No. 7,336,515.

Generally, a single-qubit gate may be implemented by a controlled rotation of an individual electron spin. The design of such an electron spin single-qubit gate has two main goals: (i) the manipulation of one electron spin should not affect neighboring qubits, and (ii) the manipulation of electron spin should be as fast as possible without decreasing the spin coherence time in presence of charge noise.

Materials to implement spin qubits may be silicon or a combination of silicon and germanium. If the spins of holes are used as qubits, a sizeable spin-orbit interaction may allow the implementation of single-qubit logic gates. If the spins of electrons are used as qubits, an oscillating Oersted field or an inhomogeneous magnetic stray-fields may be used to implement single-qubit logic gates. The magnetization in a magnet generates a magnetic field outside of the magnet called the stray field. The magnetization also generates a magnetic field inside the magnet called the demagnetizing field. The total magnetic field in a region containing magnets is the sum of the stray fields of the magnets and the magnetic field due to any free current or displacement currents.

Some embodiments of the disclosure provide a magnetic stray-field system in which a magnetic stray-field is employed for implementing the manipulation of electron spin qubits. The electron wavefunction is spatially displaced by an electric field in a region where a magnetic stray-field gradient exists. If subjected to an oscillating electric field, the electron wavefunction is periodically displaced. Since the displacement takes place in a region with a magnetic field gradient, the spatial motion of the electron wavefunction translates into an oscillating magnetic field in its reference frame. If the oscillation frequency is matched to the spin precession frequency in the total magnetic field at the dot position, the spin can be rotated via electric dipole spin resonance (EDSR). For such resonant spin rotation, the oscillating magnetic field requires a component perpendicular to the total magnetic field. The speed at which the electron spin is rotated is directly proportional to the gradient of the perpendicular stray field that the electron is experiencing, so increasing this gradient results in a shorter manipulation time.

Charge noise is a known source of local electric field variations in electronic solid-state devices. If magnetic structures are used for spin manipulations, the combination of magnetic gradients and charge noise may lead to decoherence due to the random spatial displacement of the electron wavefunction, which negatively affects the performance of the device. Two types of magnetic gradients are to be distinguished from each other: (i) driving gradient (the gradient of the stray field that is perpendicular to the mean total magnetic field) that is used for the EDSR manipulation, and (ii) decoherence gradient (the gradient of the stray field that is longitudinal or parallel with the mean total magnetic field) that when coupled with charge noise leads to dephasing. It is therefore desirable to maximize the driving gradient while minimizing the decoherence gradient for improving device performance.

Increasing the number of qubits may lead to improvement in quantum computation power, provided that each qubit can be individually manipulated. In some embodiments, during EDSR manipulation the electron wavefunction is displaced via an electric field, which results from applying an oscillating voltage on a neighboring electrode. The voltage applied to one gate may affect multiple qubits, causing the displacement of multiple electron wavefunctions and therefore manipulation of multiple qubits. To avoid unintended manipulation of multiple qubits, the magnets in some embodiments are designed such that the stray-fields lead to different total magnetic fields at different qubit locations. Thus, the frequency of the applied voltage will match only the Larmor frequency of one qubit, and the manipulation of a single qubit is made possible.

The qubit system using magnetic stray-field to implement electron spin qubits has the following characteristics: (1) high driving gradient, which allows fast manipulation time, (2) low decoherence gradients at the qubit location, so that spin decoherence due to charge noise is small, and (3) differences in local magnetic field among neighboring electrons, so that single qubit addressability is made possible.

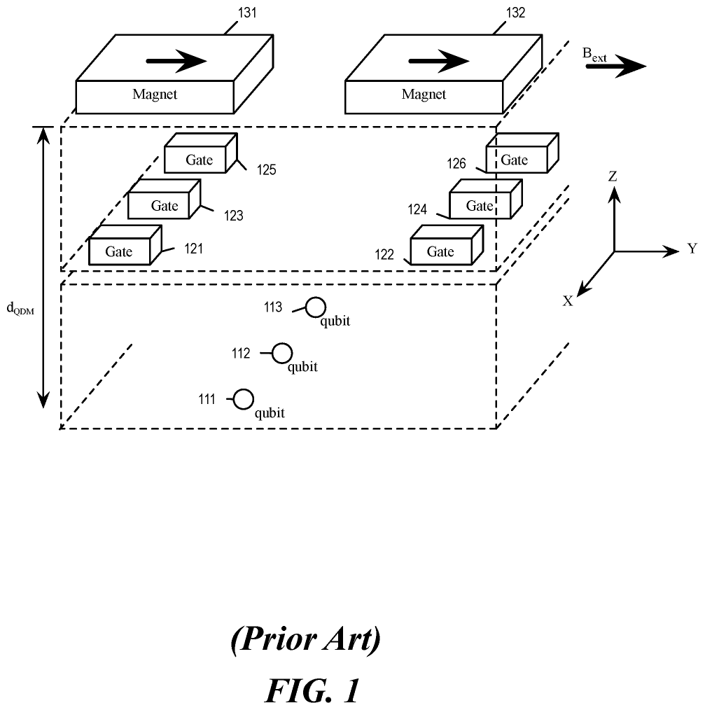

FIG. 1 conceptually illustrates a current design for EDSR driven electron-spin qubits, in which quantum dots (QDs) are arranged in a 1D array. In this design, the magnetic structures generating the magnetic stray-field are placed around 100 nm or more above the layer where the electrons qubits are stationed. This is due to the constraints set by the gates needed to create and control the quantum dot (QD) hosting the electron spin qubit. The QDs are arranged in a 1D array and are displaced by applying microwave-signals on lateral gate electrodes for generating EDSR, which further increases the number of gates needed. This arrangement sets constraints on which direction the electrons can be moved and which gradient can be leveraged to achieve EDSR. The figure shows the qubits 111-113, the gates 121-126 used to apply a lateral electric field and thus implement (in combination with the magnets) EDSR. The magnets 131 and 132 are responsible for the inhomogeneous stray-fields (with arrows showing their magnetization directions). The distance between the magnets 131-132 and the qubit (d_{QDM}) is at least 100 nm. In the figure, the displacement of the electron wavefunction for EDSR is along the y-direction, which sets the following gradients categorization: dBz/dy and dBx/dy as driving gradients, dBy/dx, dBy/dy, dBy/dz as main decoherence gradient. The total magnetic field at the qubit location mainly lies along the y-direction (due to an external field Bₑₓₜ and the magnetization of the magnets).

In this system, the gradients are strongest at the very edge of the magnets, so that the distance between magnets and QD may hinder exploiting the full potential of the stray-field. To still reach acceptable gradients to drive the spin manipulation, the magnetic structures are of micrometer size (˜1 μm), which may hinder scalability. The size of the magnets may hinder the creation of driving gradient-free regions close to the QD location, where the electron wavefunction may be displaced in order to protect the qubit during the manipulation of adjacent qubits. The design of the magnets may be chosen to accommodate the size of the magnets and to be robust against misplacement during fabrication. Unfortunately, this may compromise the maximal achievable gradients.

Some embodiments provide a qubit system that uses magnetic structures with nanomagnets to improve the speed of the spin manipulation while retaining coherence. The design of the nanomagnets allows the magnets to be placed much closer to the QD (e.g., ≤100 nm), improving driving gradient, creating gradient-reduced regions close to the QD location, and allowing the scalability potential of silicon electron spin qubits. In some embodiments, the qubit system is a device or apparatus that includes at least a row of QDs where the magnetic structures generating the stray-field are placed in the same plane as the QDs and at the side of the row.

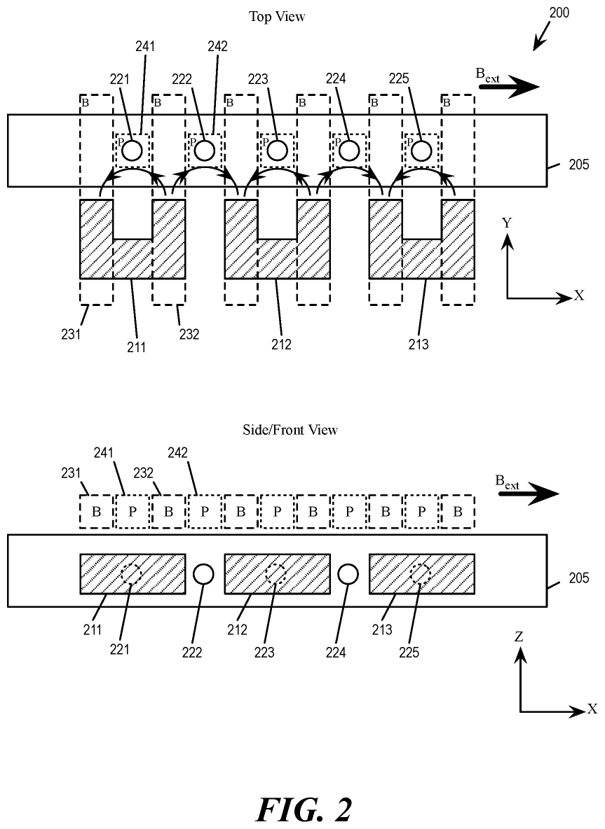

FIG. 2 illustrates a qubit system 200 with a nanomagnet design for magnetic stray-field. The stray-field of the qubit system 200 is generated by the nanomagnets 211-213. The figure illustrates field lines of the stray-field and the gates used to create the QDs. As illustrated, the QDs are implemented in a semiconductor structure or device 205 (e.g., FinFET or nanowire). A series of gates are installed above the semiconductor structure 205. Gates labeled “P”, or plunger gates (including gates 241 and 242) are used to form the QDs (thus the plunger gates are directly above the QDs in the z-direction). Gates labeled “B”, or barrier gates (including gates 231 and 232), are placed in spaces between the QDs and above the arms of the horseshoe-shaped magnets or magnetic structures 211-213. The plunger gates are used to control the electrical potentials of individual QDs. The barrier gates are used to control tunneling and thereby control exchange interactions between the adjacent QDs.

The magnetic structures 211-213 are in a configuration that places the magnets 211-213 in the same plane as QDs 221-225 and at the side of the row of QDs. (For simplicity, only three magnets 211-213 and 5 QDs 221-225 are depicted, but this configuration can be extended laterally to the desired number of structures.) The magnetic structures 211-213 are placed within 100 nm from the qubits. This proximity between the magnetic structures 211-213 and the QDs allows the driving gradients to be enhanced at the QDs. The QDs are positioned based on the positions of the magnetic structures. In some embodiments, the QDs are positioned based on (e.g., aligned with) (i) the centers of individual magnetic structures in the array of magnetic structures and (ii) the centers of gaps between individual magnetic structures. In some embodiments, the average distance between two magnetic structures is the same (or is half as much) as the average distance between two QDs, but individual positions of magnets or QDs may be variable. In some embodiments, the absolute alignment of a magnet's center and a QD's center can be variable (i.e., by individual or global offsets).

During EDSR manipulation, the qubit will be displaced along the direction of the applied external field (Bₑₓₜ), which is parallel to the direction of the linear array direction. In some embodiments, the strength of the external field Bₑₓₜ is adjusted to allow the magnetization of the magnetic structure to lie along the arms of the magnet but not forcibly aligned with the external field Bₑₓₜ.

FIG. 2 illustrates a design of the magnets tailored to a 1D array of qubits. The design is employed to generate a strong driving gradient along the direction of the QD row while minimizing the decoherence gradient. The orientation of driving gradient, displacement direction, and external field is entirely different from the current designs of 1D array of QDs illustrated in FIG. 1. This design achieves (1) creation of a sweet spot for the placement of the qubits, where the driving gradient is maximized while at the same time decoherence gradients are minimized; (2) stronger gradients at the QD location with respect to current micrometer-sized magnets; (3) creation of regions with different stray-field direction in narrower regions (facilitating the addressability of each electron); (4) creation of gradient-reduced zones to shuttle or shield the electron when it has to be protected during manipulation of neighboring qubits; (5) creation of spin-qubit arrays with identical characteristics (due to the repeated nanomagnet geometry for each qubit); (6) implementation of 2D arrays of spin qubits; (7) reduction of the required amount of gates due to the use of magnetic gates; and (8) implementation of EDSR by displacing the individual electron wavefunction along the direction of the 1D array of qubits. This magnetic structure can also be used to implement other functions, such as magnetic gates of qubits or wrap-around gates that control current flows in FinFETs.

FIG. 2 illustrates a sequence of horseshoe-shaped nanomagnets that are facing the QDs. The QDs are created as a 1D array between the arms of the magnets. The QDs are located at positions alternating between the centers of the magnets and the gaps between the magnets. The elongated form of the magnets' arms enhances the shape anisotropy contribution, forcing the magnetization to orient essentially along the longest axis, and enhancing the stray-field at the QD locations. The size of each horseshoe-shaped nanomagnet is around 1 μm or smaller.

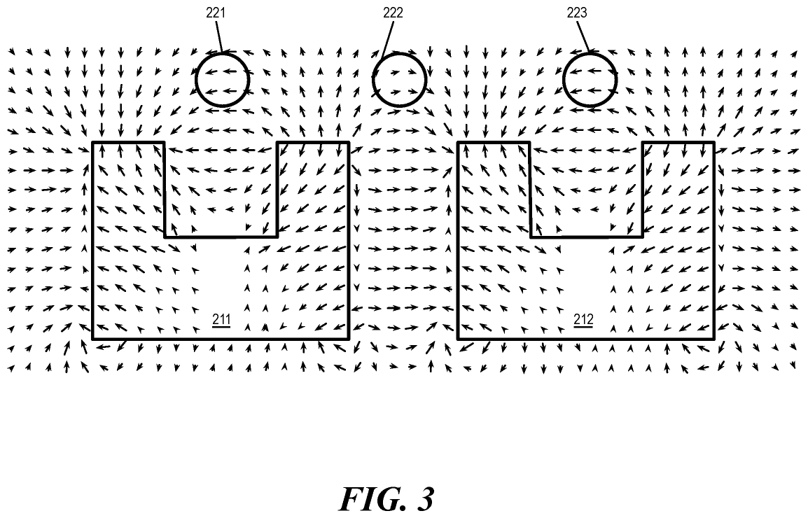

FIG. 3 illustrates the stray-field outside the magnets and the demagnetizing field within the magnets resulting from the horseshoe magnetic structure. The positions of the magnets 211 and 212 are overlayed on top of the stray-field. For each horseshoe shaped magnet, the shape helps closing the magnetic field lines between the two separated arms with opposite magnetization. Stray-field flux closure causes the stray-field direction to oscillate periodically between the arms of the magnets, which sets different Larmor frequencies (rate of precession of magnetic moment of an object about an external magnetic field) at each of the QD/qubit positions. This in turn improves single addressability of each qubit in the QD array.

In addition, the periodic change of the stray-field direction implies that there are periodic minima in the driving gradient, where each electron wavefunction can be displaced so electrons can be individually manipulated without affecting other electron qubits. Moreover, this design is beneficial for minimizing decoherence due to charge noise. As illustrated in FIG. 3, the variation of the stray-field along the QD array at the qubit positions can be minimized along the displacement direction of the qubits.

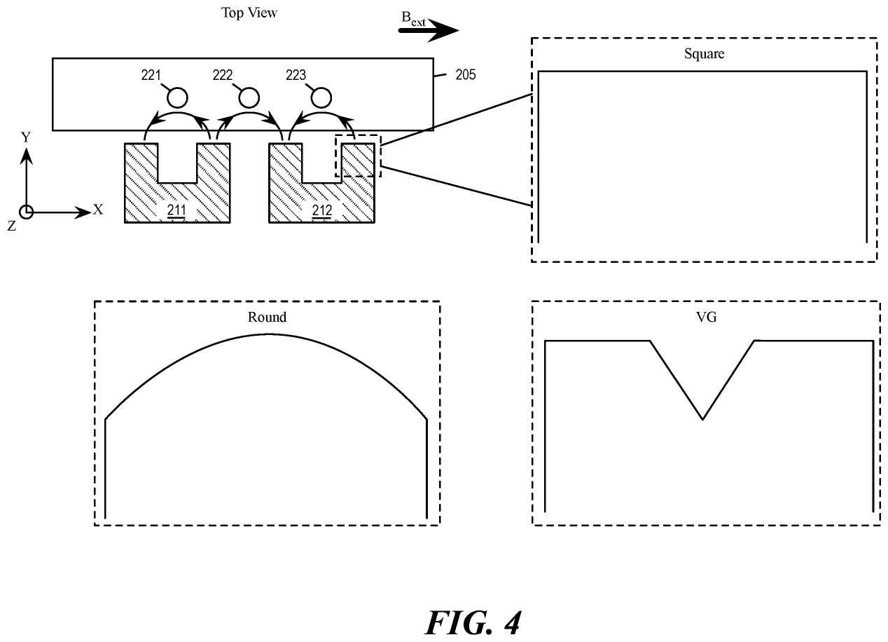

FIG. 4 illustrate various designs for the ending part (or the pole) of the arm of a nanomagnet. The figure shows some possible designs for the magnets, and possible shapes for the arm ending, named: “square”, “VG” and “round”. The shape “VG” has a notch, which is shown here as a triangle but can be of any other shape.

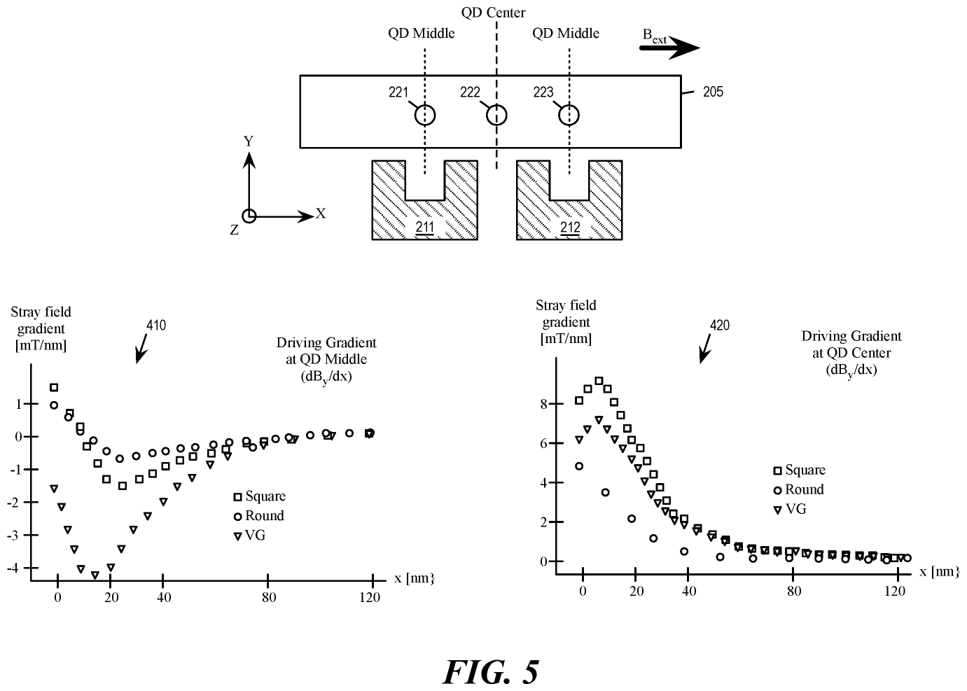

FIG. 5 shows two plots 410 and 420 that respectively correspond to driving gradients at two different types of QD positions, calculated with zero-temperature micromagnetic simulations. The simulation has been performed with the micromagnetic simulation package mumax³, assuming a saturation magnetization of 1.9e6 A/m (which corresponds to Fe₆₅Co₃₅-alloy) and an exchange stiffness of 10 pJ/m. Iron, cobalt or permalloy may also be suitable as materials for the magnet.

The plot 410 shows the driving gradient at the middle of a magnet (“QD middle”) for the three different designs shown in FIG. 4 (“square”, “VG”, and “round”). The plot 420 shows the driving gradient at the center of a gap between two neighboring magnets (“QD center”) for the three different designs. It is empirically determined that, of the three example designs for magnet's arm ending (“square”, “VG”, and “round”), the “square” design results in the highest driving gradient, but the design “VG” shows the best homogeneity in gradient between the different QD locations.

The design of the nanomagnets can be further refined. In some embodiments, the poles of the magnet are modified depending on (i) how close the magnet can be placed to the electron location, (ii) the material used for constructing magnet, and (iii) the overall shape of the magnet. For example, due to shape anisotropy, the notch on the pole in the “VG” design facilitates the formation of two magnetic domains with opposite magnetization direction between the two sides. This helps the magnetization at the very end of the pole to align along the stray-field direction and further enhances the gradient in the region between the two arms of the magnet (“QD middle”). The “round” design is determined to be the best compromise between ease of fabrication and achievable gradient, reaching 2 mT/nm at 20 nm distance from the edge of the magnet. In some embodiments, the shape or design of the poles of the magnets is chosen to contribute to increase the stray-field as much as possible at the poles.

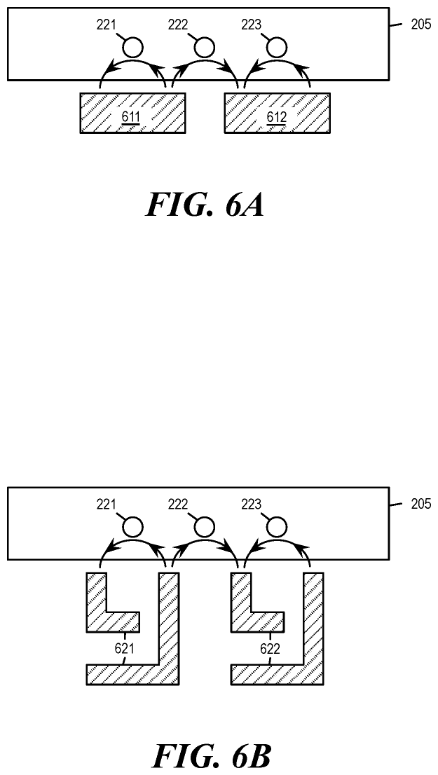

In some embodiments, each magnetic structure may have a shape that is different from the horseshoe shape shown in FIGS. 2-5, as long as the magnetization is set perpendicular to the QD array; or any other shape which makes two poles. FIGS. 6A-B illustrates magnetic structures with alternative shapes that are used to support the QDs 221-223. FIG. 6A illustrates rectangularly shaped magnetic structures 611 and 612. FIG. 6B illustrates y-shaped magnetic structures 621 and 622. As illustrated, unlike the magnetic structures 211-213 and 611-612 in which each magnetic structure consists of one magnet (one rectangle or one horseshoe), each of the y-shaped magnetic structures 621-622 includes two magnets.

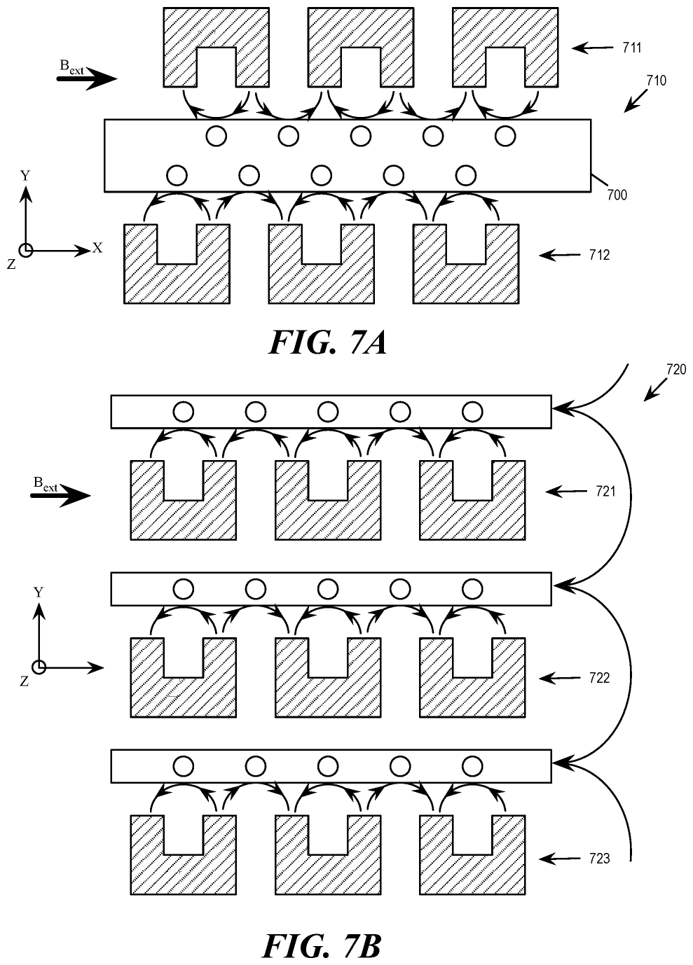

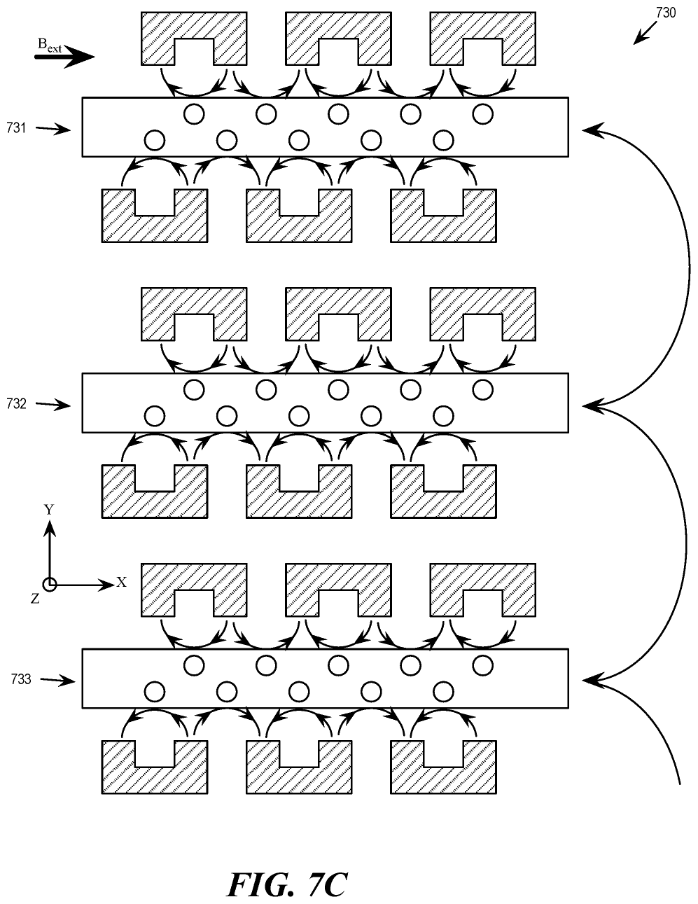

For some embodiments, the configuration of magnetic structures and the QDs can also be duplicated along the y-direction, creating 2D arrays of QDs. FIGS. 7A-C conceptually illustrates examples configuration of magnetic structures that forms 2D arrays of QDs for a EDSR qubit system. FIG. 7A illustrates a configuration of magnetic structures in which an upper layer and a lower layer of magnetic structures are used to create a 2×N array of QDs in a semiconductor structure. The configuration can be extended along the x direction to create the desired number of qubits. Moreover, the upper layer of magnets can be removed, transforming the upper layer of qubits into a row of ancilla qubits.

FIG. 7B illustrates a configuration of magnetic structures in which multiple 1D arrays of magnetic structures are used to create a M×N array of QDs. The configuration can be extended along the x-direction and/or the y-direction to the desired number of qubits as the different arrays can be connected.

FIG. 7C illustrates a configuration of magnetic structures in which multiple 2×N arrays of QDs are interconnected in the y-direction to create a 2M×N array of QDs. The configuration can also be extended along the x-direction and/or the y-direction to the desired number of qubits.

The design of the qubit system 200 is compatible with various magnetic structures. For example, gates can be made of magnetic material, helping improving addressability or enhancing the driving gradient. In some embodiments, FeCo-alloy is used as material for the gates, iron, cobalt or permalloy or generally alloys containing one or more of the ferromagnetic elements (Fe, Co, Ni, Gd) may also be suitable. As an example, the plunger gates in FIG. 2 can be made of magnetic material, which would further improve the driving gradient.

The magnetic structure may also be electrically conductive. This allows different voltages to be applied on each of the individual magnetic structures so that the electronic wavefunctions can be selectively displaced. Thus, the use of the magnetic gates can reduce the number of components used to implement and drive the qubits. The use of magnetic gates can also enhance the addressability and manipulation speed of individual qubits.

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. An apparatus comprising:
a semiconductor structure;
an array of two or more gates above the semiconductor structure to form a linear one-dimensional (1D) array of two or more quantum dots (QDs) in the semiconductor structure; and
an array of two or more magnetic structures generating stray fields in the same plane as the array of QDs,
wherein the 1D array of QDs comprises QDs that are positioned between poles of individual magnetic structures in the array of magnetic structures.

2. The apparatus of claim 1, wherein each magnetic structure in the array of magnetic structures comprises two separated arms that correspond to the two poles of a magnet, wherein the center of each magnetic structure is at the middle position between the two arms.

3. The apparatus of claim 2, wherein the array of gates comprises interleaving plunger gates that are aligned with the QDs and barrier gates that are aligned with the poles of the magnetic structures.

4. The apparatus of claim 2, wherein an arm of the magnetic structure has an end with a triangular notch.

5. The apparatus of claim 2, wherein an arm of the magnetic structure has a rounded end.

6. The apparatus of claim 2, where an external field is applied in a direction that is parallel to the linear 1D array of QDs.

7. The apparatus of claim 6, wherein the external field is adjusted to allow the magnetization of each magnetic structure to lie along the arms of the magnetic structure but not aligned with the external field.

8. The apparatus of claim 1, wherein the array of gates comprises magnetic materials, and each magnetic structure comprises a combination of iron, cobalt, nickel, and gadolinium.

9. The apparatus of claim 1, wherein at different QD positions, different magnetic fields exist leading to different Larmor frequencies.

10. The apparatus of claim 1, wherein the array of magnetic structures is placed within 100 nm of the array of QDs.

11. The apparatus of claim 1, wherein the 1D array of QDs comprises a first set of QDs that are positioned based on centers of individual magnetic structures in the array of magnetic structures and a second set of QDs that are positioned based on centers of gaps between individual magnetic structures in the array of magnetic structures.

12. A method comprising:
forming a linear one-dimensional (1D) array of two or more quantum dots (QDs) in a semiconductor structure by using an array of two or more gates above the semiconductor structure; and
generating stray fields in the same plane as the array of QDs by using an array of two or more magnetic structures,
wherein the 1D array of QDs comprises QDs that are positioned between poles of individual magnetic structures in the array of magnetic structures.

13. The method of claim 12, further comprising forming a two-dimensional (2D) array of QDs by interconnecting two or more instances of the 1D array of QDs.

14. The method of claim 12, wherein each magnetic structure in the array of magnetic structures comprises two separated arms that correspond to the two poles of a magnet, wherein the center of each magnetic structure is at the middle position between the two arms.

15. The method of claim 14, wherein the array of gates comprises interleaving plunger gates that are aligned with the QDs and barrier gates that are aligned with the poles of the magnets.

16. The method of claim 14, wherein an arm of the magnetic structure has an end with a triangular notch.

17. The method of claim 14, further comprising applying an external field in a direction that is parallel to the linear 1D array of QDs and adjusting the external field to allow the magnetization of each magnetic structure to lie along the arms of the magnetic structure but not aligned with the external field.

18. The method of claim 12, wherein at different QD positions, different magnetic fields exist leading to different Larmor frequencies.

19. The method of claim 12, wherein the generated stray-fields comprise gradient-reduced zones for protecting electrons during manipulation of neighboring qubits.

20. An apparatus comprising:
a semiconductor structure;
an array of two or more gates above the semiconductor structure to form a linear two-dimensional (2D) array of two or more quantum dots (QDs) in the semiconductor structure; and
an array of two or more magnetic structures generating stray fields in the same plane as the array of QDs,
wherein the 1D array of QDs comprises QDs that are positioned between poles of individual magnetic structures in the array of magnetic structures.
